(19) United States
(12) Patent Application Publication
(10) Pub. No.: US 2005/0227017 A1
(43) Pub. Date: Oct. 13, 2005

(54) Low temperature deposition of silicon nitride

(76) Inventors: Yoshihide Senzaki, Austin, TX (US); Aubrey L. Helms JR., Los Gatos, CA (US)

Correspondence Address: Maria S. Swiatek;DORSEY & WHITNEY LLP, Suite 3400, 4 Embarcadero Center, San Francisco, CA, 94111-4187, US

(21) Appl. No.: 10/976,697

(22) Filed: Oct. 28, 2004

Related U.S. Application Data
(60) Provisional application No. 60/518,608, filed on Oct. 31, 2003.

(51) Int. Cl. H05H 1/24; B05D 1/22; H01L 21/31

(52) U.S. Cl. 427/459; 438/791

(57) ABSTRACT

A novel class of volatile liquid precursors based on amino substituted disilane compounds is used to form silicon nitride dielectric materials on the surface of substrates. This class of precursors overcomes the issues of high deposition temperatures and the formation of undesirable by-products that are inherent in the present art. In another aspect, methods of depositing silicon nitride films on substrates are provided.

### RELATED APPLICATIONS

This application claims the benefit of and priority to U.S. Provisional Application Ser. No. 60/518,608 filed Oct. 31, 2003, the disclosure of which is hereby incorporated by reference in its entirety.

### BACKGROUND

This invention relates generally to the field of semiconductors and more specifically to methods for deposition of silicon nitride materials useful in semiconductor devices and integrated circuits.

Silicon nitride materials are widely used in the semiconductor industry due to their high dielectric constant, high dielectric breakdown voltage, superior mechanical properties and inherent inertness. For instance, silicon nitride materials have been used as gate dielectrics for semiconductor transistors, insulators between metal levels, masks to prevent oxidation and diffusion, etch masks in multilevel photoresist structures, passivation layers, and spacer materials in transistors.

There are known methods and precursors for deposition of silicon nitride films. Conventionally, low-pressure chemical vapor deposition (LPCVD) is used for deposition of silicon nitride using dichlorosilane (DCS) (SiC₁₂H₂) and ammonia (NH₃) precursors. High deposition temperatures greater than 750° C. are typically employed in LPCVD to obtain reasonable growth rates and uniformities and good film properties. The drawbacks of LPCVD method using DCS and ammonia are the impact of the high process temperatures on thermal budget and the formation of by-product ammonium chloride (NH₄Cl), which can cause particulate contamination. Ammonium chloride accumulates at the exhaust of the furnace system, plumbing lines, and pumping system. These deposits require frequent cleaning and result in significant down time for processing systems.

Alternative methods for deposition of silicon nitride films include plasma enhanced chemical vapor deposition (PECVD) using silane (SiH₄) and nitrogen (N₂) or ammonia (NH₃) precursors. The drawbacks of the PECVD methods are the difficulties of stoichiometry control of the silicon nitride films and the incorporation of undesired hydrogen element in the silicon nitride films. Further, PECVD processes are not suitable for front-end-of-line (FEOL) applications due to plasma damage to the active regions of the device.

As the lateral and vertical dimensions are scaled down in ultra-large-scale integration applications, self-aligned metal silicide processes are used to lower sheet resistance of gate electrodes and source/drain series resistance to increase device performance and reduce resistance-capacitance delay. Low temperature deposition of silicon nitride provides a number of benefits for this type of applications. Silicon nitride deposition below 600° C. is compatible with metal silicide applications, and silicon nitride films deposited below 600° C. have superior performance as sidewall spacers in reducing junction leakage between gate and source/drain.

Several new silicon precursors have been developed for low temperature silicon nitride deposition. Silicon tetraiodide (SiI₄) has been used to deposit silicon nitride at temperatures between 400° C. and 500° C. However, SiI₄ precursor is in solid state at room temperature and has a low vapor pressure, and therefore complicates the chemical delivery into a process chamber. Further, the chemical reaction with SiI₄ may produce by-product NH₄I that condenses on cool surfaces and causes particulate contamination. Hexachlorodisilane (HCD) (Si₂Cl₆) has also been used to form silicon nitride below 500° C. However, HCD precursor is a safety risk due to its shock sensitivity. Further, the chemical reaction with HCD during deposition may produce by-product NH₄Cl that condenses on cool surfaces and causes particulate contamination. Aminosilane compounds such as bis(t-butylamino) silane (BTBAS) (SiC₈N₂H₂₂) have been developed for deposition of silicon nitride. BTBAS is a halogen-free precursor that can be reacted with NH₃ to form silicon nitride, but only at temperatures greater than about 550° C.

Therefore, there is a need to develop new precursors and methods for deposition of silicon nitride at low temperatures to solve these and other problems of prior art precursors and deposition methods.

### SUMMARY

In one embodiment the present invention provides alkylamino substituted disilane compounds of the formula: ([(R¹R²N)₃₋ₓHₓSi—Si(NR³R⁴)_{3-y}H_{y}]) wherein R¹, R², R³, and R⁴ are independently any linear, branched, or cyclic alkyl group, or substituted alkyl group, and x, y=0, 1, or 2, to deposit silicon nitride films on the surface of a substrate. Of particular advantage, the deposition method is carried out at low temperatures, for example at temperatures equal to or less than 600° C., or equal to or less than 500° C.

In another embodiment the alkylamino substituted disilane compound is reacted with a nitrogen source, such as but not limited to: ammonia, hydrazine, and nitrogen, to form a silicon nitride layer of film on the wafer. In an alternative embodiment, the amino substituted disilane compound is reacted with nitrogen radical(s) to form a silicon nitride layer on the wafer. The nitrogen radical(s) may be formed from a variety of processes, such as but not limited to: in-situ plasma generation, remote plasma generation, downstream plasma generation, and photolytic generation.

In another aspect of the present invention novel alkylamino substituted disilane compounds are provided of the formula: [(R¹R²N)₃₋ₓHₓSi—Si(NR¹R⁴)_{3-y}H_{y}] wherein R¹, R², R³, and R⁴ are independently any linear, branched, cyclic ar alkyl group, or substituted alkyl group, and x, y=0, 1, or 2. In some embodiments, R¹, R², R³, and R⁴ are independently substituted or unsubstituted C₁-C₆ alkyl group respectively. In some embodiments, R¹, R², R³, and R⁴ are methyl group respectively.

In another embodiment the alkylamino substituted disilane compound is reacted with a nitrogen source selected from the group comprising ammonia, hydrazine, and nitrogen, to form a silicon nitride layer of film on the wafer. In an alternative embodiment, the amino substituted disilane compound is reacted with nitrogen radical(s) to form a silicon nitride layer on the wafer. The nitrogen radical(s) may be formed from a variety of processes, such as but not limited to: in-situ plasma generation, remote plasma generation, downstream plasma generation, and photolytic generation.

### DETAILED DESCRIPTION

The present invention provides a method for deposition at low temperatures of silicon nitride films useful in fabrication of semiconductor devices such as metal-oxide-semiconductor field effect transistors (MOSEFTs) and MOS capacitors. In general, the method of the present invention comprises the step of reacting an alkylamino substituted disilane compound with a nitrogen source to form silicon nitride.

The alkylamino substituted disilane compound of the present invention has the following general formula:
[(R¹R²N)₃₋ₓHₓSi—Si(NR³R⁴)_{3-y}H_{y}]
where R¹, R², R³, and R⁴ are independently any linear, branched, or cyclic alkyl group, or substituted alkyl group, and x, y=0, 1, or 2. In one embodiment, R¹, R², R³, and R⁴ are independently substituted or unsubstituted C₁-C₆ alkyl group. In another embodiment, R¹, R², R³, and R⁴ are methyl group respectively.

The deposited silicon nitride films using the alkylamino substituted disilane show superior uniformities. The alkylamino substituted disilane has the property to deposit silicon nitride films at low temperatures by atmospheric pressure chemical vapor deposition (APCVD), LPCVD or atomic layer deposition (ALD). For example, the deposition using alkylamino substituted disilane can be carried out by APCVD, LPCVD or ALD at a temperature in the range from about 300 to about 600° C. In some embodiments, the deposition using the alkylamino substituted disilane is carried out by APCVD, LPCVD or ALD at a temperature equal to or less than 600° C. In some embodiments, the deposition is carried out by APCVD, LPCVD or ALD at a temperature equal to or less than 500° C. In some embodiments, the deposition is carried out by APCVD, LPCVD or ALD at a temperature equal to or less than 400° C.

While not intending to limit the present invention to a particular theory, it is believed that the advantages of low temperature deposition using alkylamino substituted disilane of the present invention may be attributed to relatively weak Si—Si bonds in the alkylamino substituted disilane compound. During pyrolysis of alkylamino substituted disilane, the Si—Si bond may be readily broken and the alkylamino groups may be readily eliminated.

Of advantage, the alkylamino substituted disilane precursor of the present invention does not contain any chlorine. Therefore, the resulting silicon nitride films are free of ammonium chloride and chlorine contamination. This is in comparison of prior art precursors such as dichlorosilane and hexachlorodisilane, where the Si—Cl bonds in the precursors lead to formation of ammonium chloride which condenses on cool surfaces and requires frequent cleaning. Further, the alkylamino substituted disilane precursor of the present invention does not contain direct Si—C bond. Therefore, the resulting silicon nitride films are carbon free.

One example of the alkylamino substituted disilane is (Me₂N)₃Si—Si(N Me₂)₃, where R¹, R², R³, and R⁴ are methyl groups, respectively, in the general formula. In this example, (Me₂N)₃Si—Si(NMe₂)₃ may be synthesized according to the following reaction mechanism:
Step 1: Me₂NH+nBuLi→Me₂NLi+C₄H₁₀
Step 2: Cl₃Si—SiCl₃+6Me₂Nli→(Me₂N)₃Si—Si(NMe₂)₃+6LiCl

For example, n-BuLi (6 mol) can be added dropwise to a solution of HNR₂ (6 moles) in hexane to form LiNR₂ in hexane. Then hexachlorodisilane (Cl₃Si—SiCl₃) (1 mole) in hexane is added dropwise to the obtained solution to form (NMe₂)₃Si—Si(NMe₂)₃. The solid by-product LiCl can be removed by filtration. The hexane solvent can be removed by distillation. The final product (NR₂)₃Si—Si(NR₂)₃ may be purified by vacuum distillation.

Of advantage, the alkylamino substituted disilane can be used for deposition of silicon nitride by various systems such as low-pressure chemical vapor deposition (LPCVD) system, atmospheric pressure chemical vapor deposition (APCVD), and atomic layer deposition (ALD). LPCVD involves chemical reactions that are allowed to take place in the pressure range of about 50 millitorr to about 10 torr. The alkylamino substituted disilane precursors of the invention allow deposition of silicon nitride at a low temperature by LPCVD in the range of about 300 to 600° C. During the deposition by LPCVD, the alkylamino substituted disilane precursor and a nitrogen source are introduced into a process chamber and diffuse to the substrate. The precursors are adsorbed on the surface of the substrate and undergo chemical reactions, forming a film on the surface. The gaseous byproducts of the reaction are desorbed and removed from the process chamber. The chemical reaction is initiated by thermal energy in the LPCVD process. The LPCVD system can be either a single wafer system or a batch system such as a horizontal or vertical furnace. These types of systems are known in the semiconductor industry. PCT Application Serial No. PCT/US03/21575 entitled “Thermal Processing System and Configurable Vertical Chamber” describes a thermal process apparatus that can be used in LPCVD, the disclosure of which is hereby incorporated by reference in its entirety.

The deposition of silicon nitride can be carried out in an atmospheric pressure chemical vapor deposition (APCVD) system. APCVD involves chemical reactions that are allowed to take place in the pressure range of about 600 torr to atmosphere pressure. The alkylamino substituted disilane precursors of the invention allow deposition of silicon nitride at a low temperature by APCVD in the range of about 300 to 600° C. During the deposition by APCVD, the alkylamino substituted disilane precursor and a nitrogen source are introduced into a process chamber and diffuse to the substrate. The precursors are adsorbed on the surface of the substrate and undergo chemical reactions, forming a film on the surface. The gaseous byproducts of the reaction are desorbed and removed from the process chamber.

The deposition of silicon nitride films can also be carried out by atomic layer deposition using the alkylamino substituted disilane precursors of the present invention at low temperatures. The temperature is typically in the range of about 100 to 600° C. The pressure of the system is typically in the range of about 50 millitorr to about 10 torr. Of advantage, the ALD process can be performed at comparatively low temperatures, which is compatible with the industry's trend toward lower temperatures. ALD has high precursor utilization efficiency, can produce conformal thin film layers and control film thickness on an atomic scale, and can be used to “nano-engineer” complex thin films. In an ALD process deposition cycle, a monolayer of a first reactant is physi- or chemisorbed onto the substrate surface. Excess first reactant is evacuated from the reaction chamber preferably with the aid of an inert purge gas. A second reactant is then introduced into the reaction chamber and reacted with the first reactant to form a monolayer of the desired thin film via a self-limiting surface reaction. The self-limiting reaction stops once the initially adsorbed first reactant fully reacts with the second reactant. Excess second reactant is evacuated, preferably with the aid of an inert purge gas. A desired film thickness is obtained by repeating the deposition cycle as necessary. The film thickness can be controlled to atomic layer accuracy by simply counting the number of deposition cycles. In some embodiments of the present invention, the alkylamino substituted disilane precursor is introduced into a reaction chamber, preferably through what is referred to as a showerhead for even distribution of gases. A variety of reaction chambers may be used and are known in the art.

In some embodiments, the alkylamino substituted disilane precursor and a nitrogen source are alternatively introduced into an ALD chamber to form a silicon nitride film by atomic layer deposition. The repetition of the cycle provides a silicon nitride film with a desired thickness.

Suitable nitrogen sources used in the present invention include nitrogen containing compounds, such as but not limited to nitrogen, NH₃ and hydrazine (N₂H₂), atomic nitrogen and the like. For deposition temperatures at about 400° C. or below, it may be optionally preferred to provide an additional energy source to activate the nitrogen source to form nitrogen radicals to facilitate deposition. Energy activation can be accomplished by any number of well known methods, such as but not limited to in-situ plasma generation, remote plasma generation, downstream plasma generation, photolytic radical generation and the like.

In some embodiments, an oxygen-containing source may also be conveyed to a process chamber to form a silicon oxynitride film. Suitable oxygen-containing source include O₂, N₂O and NO in conjunction with the NH₃.

The silicon nitride films deposited using the alkylamino substituted disilane have various applications. They can be used as gate dielectrics for their high dielectric constant, insulators between metal levels, masks to prevent oxidation and diffusion, etch masks in multilevel photoresist structures, passivation layers, and spacer materials in transistors. The silicon nitride films deposited at low temperatures are particularly suitable as spacer materials. Sidewall spacers are protective layers on the wafer to protect stacked structures such as gate stacks during a self-aligned contact etching process. As the lateral and vertical dimensions are scaled down in ultra-large-scale integration applications, self-aligned metal silicide processes are used to lower sheet resistance of the gate electrode and source/drain series resistance, thus increasing device performance and reducing resistance-capacitance delay. For example, gate stacks formed of at least a dielectric layer and an overlying conductive layer, e.g., doped polysilicon, are fabricated on a substrate and are spaced apart from one another. An insulative protective layer such as a silicon nitride layer is formed to overlay the arrays of gate stacks. Low temperature deposition of silicon nitride provides a number of benefits for this type of structure. Silicon nitride deposition below 500° C. is compatible with the self-align metal silicide process, and has superior performance as sidewall spacers in reducing junction leakage between gate and source/drain.

The following examples are provided to illustrate the present invention and are not intended to limit the scope of the invention in any way.

### EXAMPLE 1

This example illustrates low pressure chemical vapor deposition of silicon nitride using alkylamino-substituted disilane with ammonia.

Alkylamino-substituted disilane (NR₂)₃Si—Si(NR₂)₃ and ammonia are used as precursors in silicon nitride deposition by LPCVD. The precursor gases are introduced into a vertical 50-wafer batch furnace using a distribution tube. An inert gas flow (N₂) of 500 sccm is included in the gas mixture. The precursor flow rate is 50 sccm and the ammonia to precursor flow ratio is 10 to 1 (total ammonia flow is 500 sccm). The deposition temperature (wafer temperature) is 450° C. and the pressure in the furnace is 250 mTorr.

### EXAMPLE 2

This example illustrates atmospheric pressure chemical vapor deposition of silicon nitride using alkylamino-substituted disilane with ammonia.

Alkylamino-substituted disilane (NR₂)₃Si—Si(NR₂)₃ and ammonia are used as precursors in APCVD. The total gas flow per injector is 25 slm. The precursor flow rate is 126 sccm and the ammonia to precursor flow ratio is 20 to I (total ammonia flow is 2500 sccm). The deposition temperature (wafer temperature) is 450° C. and the pressure is 760 Torr.

### EXAMPLE 3

This example illustrates atomic layer deposition of silicon nitride using alkylamino-substituted disilane with ammonia.

Alkylamino-substituted disilane (NR₂)₃Si—Si(NR₂)₃ and ammonia are used as precursors in silicon nitride deposition by ALD. The precursor gases are introduced into a single wafer ALD system through a showerhead with separate channels for alkylamino-substituted disilane and ammonia respectively. An inert gas (Ar) flow of 500 sccm is included in the gas mixture. The alkylamino-substituted disilane precursor flow rate is 50 sccm and the ammonia to disilane flow ratio is 10 to 1 (total 10 ammonia flow is 500 sccm). Atomic layer deposition is achieved using an alternating series of pulses (chemical pulse, inert gas purge, ammonia pulse, inert gas purge). The pulse times are 0.5/2/2/4 seconds respectively. The deposition temperature (wafer temperature) is 400° C. and the pressure is 1 Torr.

### EXAMPLE 4

This example illustrates low pressure chemical vapor deposition of silicon oxide using alkylamino-substituted and ozone.

Alkylamino substituted disilane (NR₂)₃Si—Si(NR₂)₃ and ozone are used in silicon oxide deposition by LPCVD. The precursor gases are introduced into a vertical 50-wafer batch furnace using a distribution tube. An inert gas flow (N₂) of 500 sccm is included in the gas mixture. The precursor flow rate is 10 sccm and the ozone to precursor flow ratio is 25 to 1 (total O₂/O₃ flow was 2.1 slm and the ozone concentration was 250 g/m²). The deposition temperature (wafer temperature) is 500° C. and the pressure is 500 mTorr.

### EXAMPLE 5

This example illustrates atmospheric pressure chemical vapor deposition of silicon oxide using alkylamino-substituted disilane and ozone.

Alkylamino-substituted disilane (NR₂)₃Si—Si(R₂)₃ and ozone are used in silicon oxide deposition by APCVD. The total gas flow per injector is 25 slm (˜15 slm N₂). The disilane precursor flow rate is 42 sccm and the ozone to precursor flow ratio is 21 to 1 (total O₂/O₃ flow is 10 slm and the ozone concentration is 180 g/m²). The deposition temperature (wafer temperature) is 500° C. and the pressure is 760 Torr.

### EXAMPLE 6

This example illustrates atomic layer deposition of silicon oxide using alkylamino-substituted disilane and ozone.

Alkylamino substituted disilane (NR₂)₃Si—Si(NR₂)₃ and ozone are used in silicon oxide deposition by ALD. Gases are introduced into a single wafer ALD system through a showerhead with separate channels for the disilane precursor and ozone. An inert gas flow (Ar) of 500 sccm is included in the gas mixture. The precursor flow rate is 50 sccm and the total O₂/O₃ flow is 500 slm and the ozone concentration is 200 g/m². Atomic layer deposition is achieved using an alternating series of pulses (chemical pulse, inert gas purge, oxidizer pulse, inert gas purge). The pulse times are 0.5/2/2/3 s respectively. The deposition temperature (wafer temperature) is 450° C. and the pressure is 1 Torr.

### EXAMPLE 7

This example illustrates low pressure chemical vapor deposition of silicon oxynitride using alkylamino substituted disilane, ammonia and nitrous or nitric oxide.

Alkylamino-substituted disilane (NR₂)₃Si—Si(NR₂)₃, ammonia as the nitrogen source and nitrous oxide or nitric oxide as the oxygen source are used in silicon oxynitride deposition by LPCVD. The gases are introduced into a vertical 50-wafer batch furnace using a distribution tube. An inert gas flow (N₂) of 500 sccm is included in the gas mixture. The precursor flow rate is 50 sccm and the ammonia to precursor flow ratio is 8 to 1 (total ammonia flow is 400 sccm). Using N₂O as the oxidizer, the oxidizer to precursor flow ratio is 10 to 1 (total nitrous oxidize flow was 500 sccm). The deposition temperature (wafer temperature) is 450° C. and the pressure is 400 mTorr.

### EXAMPLE 8

This example illustrates atmospheric pressure chemical vapor deposition of silicon oxynitride using alkylamino-substituted disilane, ammonia and nitrous or nitric oxide.

Alkylamino-substituted disilane (NR₂)₃Si—Si(NR₂)₃, ammonia as nitrogen source and nitrous oxide or nitric oxide as oxygen source are used in silicon oxynitride deposition by APCVD. The total gas flow per injector is 25 slm. The precursor flow rate is 125 sccm and the ammonia to precursor flow ratio is 20 to 1 (total ammonia flow was 2500 sccm). Using N₂O as the oxidizer, the oxidizer to precursor flow ratio is 25 to 1 (total nitrous oxidize flow is 3125 sccm). The deposition temperature (wafer temperature) is 450° C. and the pressure is 760 Torr.

### EXAMPLE 9

This example illustrates atomic layer deposition of silicon oxynitride using alkylamino-substituted disilane, ammonia and nitrous or nitric oxide.

Alkylamino-substituted disilane (NR₂)₃Si—Si(NR₂)₃, ammonia as nitrogen source and nitrous oxide or nitric oxide as oxygen source are used in silicon oxynitride deposition by ALD. Gases are introduced into a single wafer ALD system through a showerhead with separate channels for the precursors. An inert gas flow (Ar) of 500 sccm is included in the gas mixture. The disilane precursor flow rate is 50 sccm and the ammonia to disilane precursor flow ratio is 8 to 1 (total ammonia flow is 400 sccm). Using N₂O as the oxidizer, the oxidizer to disilane precursor flow ratio is 10 to 1 (total nitrous oxidize flow was 500 sccm). Atomic layer deposition is achieved using an alternating series of pulses (chemical pulse, inert gas purge, ammonia pulse, inert gas purge, oxidizer pulse, inert gas purge). The pulse times are 0.5/2/2/3/3 second respectively. The deposition temperature (wafer temperature) is 400° C. and the pressure is 1 Torr.

The foregoing description of specific embodiments and examples of the invention have been presented for the purpose of illustration and description, and although the invention has been described and illustrated by certain of the preceding examples, it is not to be construed as being limited thereby. They are not intended to be exhaustive or to limit the invention to the precise forms disclosed, and many modifications, improvements and variations within the scope of the invention are possible in light of the above teaching. It is intended that the scope of the invention encompass the generic area as herein disclosed, and by the claims appended hereto and their equivalents.

1. A method of depositing a silicon nitride material on a substrate characterized in that an alkylmino substituted disilane compound of the formula:
[(R¹R²N)₃₋ₓHₓSi—Si(NR³R⁴)_{3-y}H_{y}]
wherein R¹, R², R³, and R⁴ are independently any linear, branched, or cyclic alkyl group, or substituted alkyl group, and x, y=0, 1, or 2, is reacted with a nitrogen source to form the silicon nitride material.

2. The method of claim 1 wherein the alkylamino substituted disilane compound is reacted with a nitrogen source selected from the group comprising ammonia, hydrazine, nitrogen, and mixtures thereof.

3. The method of claim 1 where the alkylamino substituted disilane compound is reacted with a nitrogen radical, said nitrogen radical being formed from a process selected from the group comprising in-situ plasma generation, remote plasma generation, downstream plasma generation, and photolytic generation.

4. The method of claim 1 wherein the method is carried out at a deposition temperature equal to or less than 600° C.

5. The method of claim 1 wherein the method is carried out at a deposition temperature equal to or less than 500° C.

6. The method of claim 1 wherein the method is carried out at a deposition temperature of equal to or less than 400° C.

7. The method of any of claims 4-6 wherein the method is carried out in a low pressure chemical vapor deposition system.

8. The method of any of claims 4-6 wherein the method is carried out in an atmospheric pressure chemical vapor deposition system.

9. The method of any of claims 4-6 wherein the method is carried out in a atomic layer deposition system.

10. The method of claim 1 wherein the alkylamino substituted disilane compound is (Me₂N)₃ Si—Si(N Me₂)₃ and Me is a methyl group.

11. The method of claim 1 further comprising reacting an oxygen containing source to form a silicon oxynitride film.

12. An alkylamino substituted disilane compound having the formula:
[(R¹R²N)₃₋ₓHₓSi—Si(NR³R⁴)_{3-y}H^{y}]
wherein R¹, R², R³, and R⁴ are independently any substituted or unsubstituted linear, branched, or cyclic alkyl group, and x, y=0, 1, or 2.

13. The alkylamino substituted disilane compound of claim 12 wherein R¹, R², R³, and R⁴ are any substituted or unsubstituted alkyl group having 1-6 carbon atoms.

14. The alkylamino substituted disilane compound of claim 13 wherein R¹, R², R³, and R⁴ are methyl groups respectively.

15. A method of synthesizing a disilane compound, comprising the steps of:
Step 1: Me₂NH+nBuLi→Me₂NLi+C₄H₁₀ and
Step 2: Cl₃Si—SiCl₃+6Me₂Nli→(Me₂N)₃Si—Si(NMe₂)₃+6LiCl.

16. The method of claim 15 further comprising the step of:
purifying the product (Me₂N)₃Si—Si(NMe₂)₃ by vacuum distillation.

17. The method of claim 1 1 wherein the oxygen-containing source includes O₂, N₂O and NO.
